(19) United States
(12) Patent Application Publication
(10) Pub. No.: US 2018/0166644 A1
(43) Pub. Date: Jun. 14, 2018

(54) TANDEM TYPE ORGANIC LIGHT EMITTING DEVICE

(71) Applicants: Corning Precision Materials Co., Ltd., Chungcheongnam-do (KR); UNIVERSITY-INDUSTRY COOPERATION GROUP OF KYUNG HEE UNIVERSITY, Gyeonggi-do (KR)

(72) Inventors: Jang Dae Youn, Chungcheongnam-do (KR); Kwang Je Woo, Chungcheongnam-do (KR); Hyung Seok Lee, Chungcheongnam-do (KR); Jang Hyuk Kwon, Chungcheongnam-do (KR); Young Hoon Son, Chungcheongnam-do (KR)

(73) Assignees: Corning Precision Materials Co., Ltd., Chungcheongnam-do (KR); UNIVERSITY-INDUSTRY COOPERATION GROUP OF KYUNG HEE UNIVERSITY, Gyeonggi-do (KR)

(21) Appl. No.: 15/541,647

(22) PCT Filed: Jan. 5, 2016
(86) PCT No.: PCT/KR2016/000073

§ 371 Date: Jul. 5, 2017

(30) Foreign Application Priority Data
Jan. 5, 2015 (KR) 10-2015-0000399
May 22, 2015 (KR) 10-2015-0071976

(51) Int. Cl. H01L 51/50; H01L 51/52; H01L 51/00

(52) U.S. Cl. CPC H01L 51/504; H01L 51/5206; H01L 51/5221; H01L 51/0097; H01L 2251/558; H01L 51/5064; H01L 51/5092; H01L 51/508; H01L 2251/5338; H01L 51/5088

(57) ABSTRACT

The present invention relates to a tandem type organic light emitting device and, more specifically, to a tandem type organic light emitting device which exhibits low operation voltage, high power efficiency and an excellent color rendering index (CRI). To this end, the present invention provides a tandem type organic light emitting device, the device comprising: a base substrate; a first electrode formed on the base substrate; a second electrode formed to oppose the first electrode; and first to third organic light emitting layers formed in sequence from the first electrode, between the first electrode and the second electrode. The first organic light emitting layer comprises a first light emitting layer for emitting blue light, the second organic light emitting layer comprises a second light emitting layer for emitting yellow light, and the third organic light emitting layer comprises a third light emitting layer for emitting red light.

### TECHNICAL FIELD

The present disclosure relates to a tandem organic light-emitting device (OLED). More particularly, the present disclosure relates to a tandem OLED having a low driving voltage, high power efficiency, and a superior color rendering index (CRI).

### BACKGROUND ART

Recently, display devices and lighting devices have been required to be, for example, lightweight, thin, highly efficient, and eco-friendly. To satisfy these requirements, studies into the use of organic light-emitting devices (OLEDs) have been actively undertaken.

OLEDs may be divided into single OLEDs, each of which has a single organic light-emitting layer, and tandem OLEDs, each of which has two or more organic light-emitting layers stacked on each other in series. Tandem OLEDs may be used in display devices or lighting devices requiring a high level of luminance and a longer lifespan due to higher reliability and longer lifespans thereof, as compared to single OLEDs.

A white OLED has different organic light-emitting layers between an anode and a cathode, to emit different colors of light. At least one charge generation layer is disposed between the organic light-emitting layers. The sequence of arrangement of the organic light-emitting layers and the distances from a cathode or an anode to the organic light-emitting layers must be optimized to improve device characteristics, such as a color rendering index (CRI), without the addition of a component having a separate function.

### RELATED ART DOCUMENT

Japanese Patent No. 4649676 (Dec. 24, 2010)

### DISCLOSURE

### Technical Problem

Accordingly, the present disclosure has been made in consideration of the above-described problems occurring in the related art, and the present disclosure proposes a tandem organic light-emitting device (OLED) having a low driving voltage, high power efficiency, and a superior color rendering index (CRI).

### Technical Solution

According to an aspect of the present disclosure, a tandem OLED may include: a base substrate; a first electrode disposed on the base substrate; a second electrode facing the first electrode; first to third organic light-emitting layers sequentially disposed from the first electrode, between the first electrode and the second electrode. The first organic light-emitting layer includes a first emissive layer generating blue light, the second organic light-emitting layer includes a second emissive layer generating yellow light, and the third organic light-emitting layer includes a third emissive layer generating red light.

A distance between the second emissive layer and the third emissive layer may be greater than a distance between the first emissive layer and the second emissive layer and a distance between the third emissive layer and the second electrode.

The distance between the second emissive layer and the third emissive layer may range from 100 nm to 300 nm.

The distance between the first emissive layer and the second emissive layer and the distance between the third emissive layer and the second electrode may be less than 100 nm.

When a distance between the first electrode and the second electrode is 500 nm or less, a distance between the first emissive layer and the second electrode may be 292 nm, a distance between the second emissive layer and the second electrode may be 200 nm, a distance between the third emissive layer and the second electrode may be 60 nm, and a distance between the first electrode and the first emissive layer may be 95 nm.

The tandem OLED may further include: a first charge generation layer situated between the first organic light-emitting layer and the second organic light-emitting layer; and a second charge generation layer situated between the second organic light-emitting layer and the third organic light-emitting layer.

The tandem OLED may further include a third charge generation layer situated between the first organic light-emitting layer and the first electrode.

A hole layer may be disposed on one surface of each of the first to third emissive layers and an electron layer may be disposed on the other surface of each of the first to third emissive layers. The hole layer may be disposed in a direction of the first electrode, and the electron layer may be disposed in a direction of the second electrode.

The base substrate may be a flexible substrate.

The base substrate may be a thin glass sheet having a thickness of 1.5 mm or less.

### Advantageous Effects

According to the present disclosure, the arrangement structure of emissive layers is optimized by controlling the sequence of arrangement of a blue emissive layer, a yellow emissive layer, and a red emissive layer disposed between an anode and a cathode and controlling the distances between the emissive layers and the cathode or between emissive layers and the anode and the distances between emissive layers. This can consequently lower the operating voltage of a tandem OLED and improve the power efficiency and color rendering index (CRI) of the tandem OLED.

### DESCRIPTION OF DRAWINGS

FIG. 1 is a schematic cross-sectional view illustrating a tandem OLED according to an exemplary embodiment;

FIG. 2 is a graph illustrating EL spectra of tandem OLEDs according to Example 1, Comparative Example 1, Comparative Example 2, and Comparative Example 3;

FIG. 3 is a graph illustrating EL spectra of tandem OLEDs according to Example 3, Comparative Example 6, and Comparative Example 7;

FIG. 4 illustrates simulated contour plots of normalized radiance intensity of normalized radiance intensity, FIG. 5 illustrates normalized radiances depending on the thicknesses of electron layers, FIG. 6 is conceptual view illustrating the thicknesses of electron layers in triple-stack tandem structures; and

FIGS. 7 and 8 illustrate power efficiencies and EL spectra of fabricated unit devices.

### MODE FOR INVENTION

Hereinafter, a tandem organic light-emitting device (OLED) according to exemplary embodiments will be described in detail with reference to the accompanying drawings.

In the following disclosure, detailed descriptions of known functions and components incorporated herein will be omitted in the case that the subject matter of the present disclosure may be rendered unclear by the inclusion thereof.

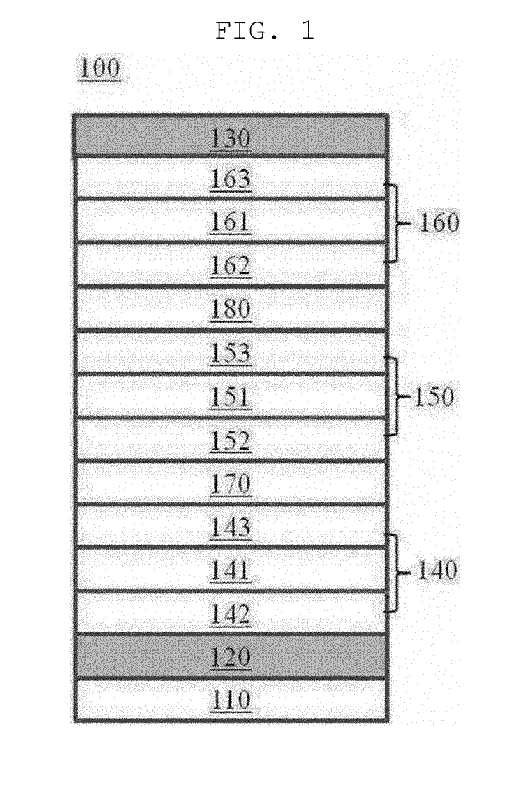

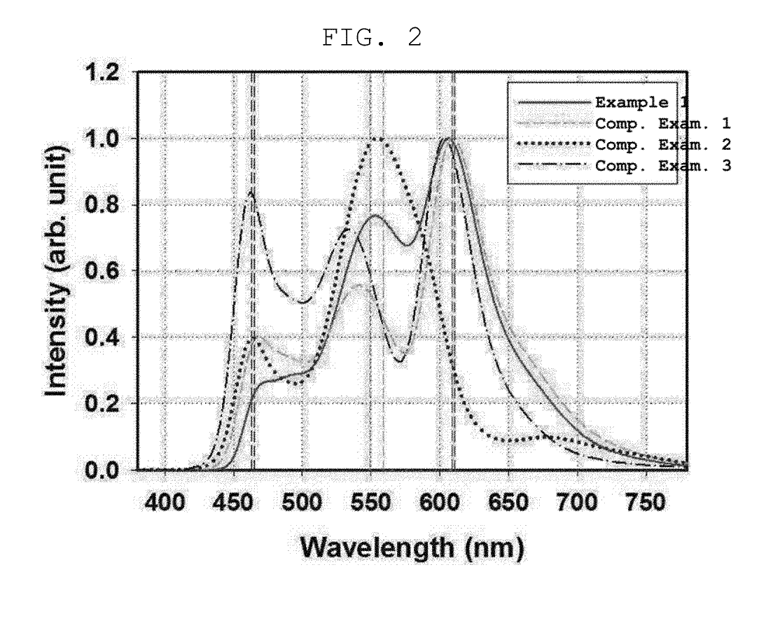

As illustrated in FIG. 1, a tandem OLED 100 according to an exemplary embodiment includes a base substrate 110, a first electrode 120, a second electrode 130, and organic light-emitting layers.

The base substrate 110 serves as a light guide through which light generated by the organic light-emitting layers exits. In this regard, the base substrate 110 is disposed in front of the organic light-emitting layers, i.e. on a path on which light generated by the organic light-emitting layers exits. In addition, the base substrate 110 serves to protect the first electrode 120, the second electrode 130, and the organic light-emitting layers from the external environment. In this regard, to encapsulate the first electrode 120, the second electrode 130, and the organic light-emitting layers, the base substrate 110 is bonded to a rear substrate (not shown) disposed above the second electrode 130 to face the base substrate 130, by means of a sealing material, such as epoxy, disposed along the outer circumferential surface of the base substrate 110. In the inner space defined by the base substrate 110, the rear substrate (not shown) facing the base substrate 110, and the sealing material disposed on the periphery of the base substrate 110 and the rear substrate (not shown), a portion of the inner space, except for a portion of the inner space occupied by the first electrode 120, the second electrode 130, and the organic light-emitting layers, may be filled with an inert gas or may be formed to have a vacuum atmosphere.

On the other hand, to improve external extraction efficiency of light generated by the organic light-emitting layers, a separate external light extraction layer (not shown) may be disposed on the outer surface of the base substrate 110 that contacts the ambient air or the base substrate 110 may have a lens array in the outer surface thereof. In addition, an internal light extraction layer (not shown) may be formed between the base substrate 110 and the first electrode 120.

The base substrate 110 may be a transparent substrate formed from any transparent material having superior light transmittance and excellent mechanical properties. For example, the base substrate 110 may be formed from a polymeric material, such as a thermally or ultraviolet (UV) curable organic film. In addition, the base substrate 110 may be formed from chemically strengthened glass, such as soda-lime glass (SiO₂—CaO—Na₂O) or aluminosilicate glass (SiO₂—Al₂O₃—Na₂O). When the tandem OLED 100 according to the exemplary embodiment is used for lighting, the base substrate 110 may be formed from soda-lime glass. In addition, the base substrate 100 may be a substrate formed from a metal oxide or a metal nitride. The base substrate 110 according to the exemplary embodiment may be a flexible substrate, in particular, a thin glass sheet having a thickness of about 1.5 mm or less. The thin glass substrate may be fabricated using a fusion process or a floating process. The rear substrate (not shown) forming an encapsulation portion with the base substrate 110 may be formed from the same material as or a different material from the base substrate 110.

The first electrode 120 is formed on the base substrate 110. The first electrode 120 is a transparent electrode acting as an anode of the tandem OLED 100. The first electrode 120 may be formed from a material selected from among materials having a greater work function to facilitate hole injection into the organic light-emitting layers, the selected material being able to enhance the transmission of light generated by the organic light-emitting layers. For example, the first electrode 120 may be formed from indium tin oxide (ITO).

The second electrode 130 is disposed to face the first electrode 120, such that the plurality of organic light-emitting layers are situated between the second electrode 130 and the first electrode 120. The second electrode 130 is a metal electrode acting as a cathode of the tandem OLED 10. The second electrode 130 may be formed from a material selected from among materials reflecting light generated by the organic light-emitting layers forwardly, i.e. in the direction of the base substrate 110, the selected material having a smaller work function to improve electron injection into the organic light-emitting layers. For example, the second electrode 130 may be a metal thin film formed from Al, Al:Li or Mg:Ag.

Two or more organic light-emitting layers are situated between the first electrode 120 and the second electrode 130 to form the tandem OLED 100. The organic light-emitting layers according to the exemplary embodiment include three organic light-emitting layers, i.e. a first organic light-emitting layer 140, a second organic light-emitting layer 150, and a third organic light-emitting layer 160, sequentially disposed between the first and second electrodes 120 and 130. The first organic light-emitting layer 140 and the second organic light-emitting layer 150 are connected via a first charge generation layer (CGL) 170 situated therebetween, while the second organic light-emitting layer 150 and the third organic light-emitting layer 160 are connected via a second CGL 180 situated therebetween.

According to the exemplary embodiment, the first organic light-emitting layer 140 includes a first emissive layer 141 generating blue light. The first emissive layer 141 may be formed from a material emitting blue light having a wavelength bandwidth of about 450±5 nm. The second organic light-emitting layer 150 includes a second emissive layer 151 generating yellow light. The second emissive layer 151 may be formed from a material emitting yellow light having a wavelength bandwidth of about 540±5 nm. The third organic light-emitting layer 160 includes a third emissive layer 161 generating red light. The third emissive layer 161 may be formed from a material emitting red light having a wavelength bandwidth of about 610±5 nm. Due to a light mixing effect of blue, yellow, and red light respectively emitted from the first to third emissive layers 141, 151, and 161, as described above, the tandem OLED 100 according to the exemplary embodiment emits white light.

The tandem OLED 100 according to the exemplary embodiment has a structure in which the first to third emissive layers 141, 151, 161 emitting blue, yellow, and red light are sequentially arranged from the first electrode 120. According to the exemplary embodiment, the distance between the second emissive layer 151 and the third emissive layer 161 may be set to be longer than the distance between the first emissive layer 141 and the second emissive layer 151 and the distance between the third emissive layer 161 and the second electrode 130. For example, the distance between the second emissive layer 151 and the third emissive layer 161 may be set to be 100 nm to 300 nm. In this case, each of the distance between the first emissive layer 141 and the second emissive layer 151 and the distance between the third emissive layer 161 and the second electrode 130 may be determined to be less than 100 nm. In addition, according to the exemplary embodiment, the distance between the second electrode 130 and the first emissive layer 141, the distance between the second electrode 130 and the second emissive layer 151, the distance between the second electrode 130 and the third emissive layer 161, and the distance between the first emissive layer 141 and the first electrode 120 are controlled to be within predetermined ranges. For example, when the distance between the first electrode 120 and the second electrode 130 is less than 500 nm, the distance between the second electrode 130 and the first emissive layer 141 may be controlled to be 292 nm, the distance between the second electrode 130 and the second emissive layer 151 may be controlled to be 200 nm, the distance between the second electrode 130 and the third emissive layer 161 may be controlled to be 60 nm, and the distance between the first emissive layer 141 and the first electrode 120 may be controlled to be 95 nm to improve the performance of the tandem OLED 100.

As described above, according to the exemplary embodiment, the first emissive layer 141 generating blue light, the second emissive layer 151 generating yellow light, and the third emissive layer 161 generating red light are sequentially arranged from the first electrode 120, between the first electrode 120 and the second electrode 130, and the distances between the emissive layers 141, 151, and 161 and the second electrode 130 are controlled. Thus, the arrangement structure of the emissive layers 141, 151, and 161 is optimized, the tandem OLED 100 according to the exemplary embodiment can realize a low operating voltage, high power efficiency, and a superior color rendering index (CRI).

The first organic light-emitting layer 140 includes a hole layer 142 disposed on one surface of the first emissive layer 141 and an electron layer 143 disposed on the other surface of the first emissive layer 141. In addition, the second organic light-emitting layer 150 includes a hole layer 152 disposed on one side of the second emissive layer 151 and an electron layer 153 disposed on the other surface of the emissive layer 151. In addition, the third organic light-emitting layer 160 includes a hole layer 162 disposed on one side of the third emissive layer 161 and an electron layer 163 disposed on the other surface of the emissive layer 161. The hole layers 142, 152, and 162 are disposed in the direction of the first electrode 120, while the electron layers 143, 153, and 163 are disposed in the direction of the second electrode 130.

Although not specifically illustrated, each of the hole layers 142, 152, and 162 may have a multilayer structure comprised of a hole injection layer (HIL) and a hole transport layer (HTL). The hole transport layer may have a multilayer structure including, for example, a p-type hole transport layer. In addition, each of the electron layers 143, 153, and 163 may have a multilayer structure comprised of an electron injection layer (EIL) and an electron transport layer (ETL). The electron transport layer may have a multilayer structure including, for example, an n-type electron transport layer.

Thus, in the first organic light-emitting layer 140, holes migrate from the first electrode 120 to the first emissive layer 141 through the hole layer 142, while electrons migrate from the first CGL 170 to the first emissive layer 141 through the electron layer 143. A third CGL (not shown) may be disposed between the first organic light-emitting layer 140 and the first electrode 120, and a hole injection layer (not shown) may be disposed between the third CGL (not shown) and the first electrode 120. In this case, in the first organic light-emitting layer 140, holes migrate from the first electrode 120 to the first emissive layer 141 through the hole injection layer, the third CGL (not shown), and the hole layer 142. In addition, in the second organic light-emitting layer 150, holes migrate from the first CGL 170 to the second emissive layer 151 through the hole layer 152, while electrons migrate from the second CGL 180 to the second emissive layer 151 through the electron layer 153. In addition, in the third organic light-emitting layer 160, holes migrate from the second CGL 180 to the third emissive layer 161 through the hole layer 162, while electrons migrate from the second electrode 130 to the third emissive layer 163 through the electron layer 163.

When a forward voltage is applied to the first electrode 120 and the second electrode 130, electrons and holes migrate to the emissive layers 141, 151, and 161 through the routes described above. Electrons and holes injected into the emissive layers 141, 151, and 161, as above, recombine with each other to generate excitons. When excitons transit from an excited state to a ground state, light is emitted. The brightness of emitted light is proportional to the amount of current flowing between the first electrode 120 acting as an anode and the second electrode 130 acting as a cathode.

### EXAMPLE 1

A tandem OLED having a multilayer structure comprised of an anode, a hole layer, a blue emissive layer, an electron layer, a CGL, a hole layer, a yellow emissive layer, an electron layer, a CGL, a hole layer, a red emissive layer, an electron layer, and a cathode was fabricated.

### COMPARATIVE EXAMPLE 1

A tandem OLED having a multilayer structure comprised of an anode, a hole layer, a yellow emissive layer, an electron layer, a CGL, a hole layer, a blue emissive layer, an electron layer, a CGL, a hole layer, a red emissive layer, an electron layer, and a cathode was fabricated.

### COMPARATIVE EXAMPLE 2

A tandem OLED having a multilayer structure comprised of an anode, a hole layer, a red emissive layer, an electron layer, a CGL, a hole layer, a yellow emissive layer, an electron layer, a CGL, a hole layer, a blue emissive layer, an electron layer, and a cathode was fabricated.

### COMPARATIVE EXAMPLE 3

A tandem OLED having a multilayer structure comprised of an anode, a hole layer, a yellow emissive layer, an electron layer, a CGL, a hole layer, a red emissive layer, an electron layer, a CGL, a hole layer, a blue emissive layer, an electron layer, and a cathode was fabricated.

TABLE 1

| @3,000 nits | Example 1 | Comp. Exam. 1 | Comp. Exam. 2 | Comp. Exam. 3 |
|---|---|---|---|---|
| Operating Voltage (V) | 10.2 | 10.9 | 10.5 | 12.3 |
| Power Efficiency | 25.6 | 14.2 | 17.5 | 6.1 |
| (lm/W) | | | | |
| CIE (x, y) | (0.453, 0.463) | (0.424, 0.393) | (0.453, 0.463) | (0.362, 0.374) |
| CRI | 75.4 | 88.5 | 41.9 | 85.9 |

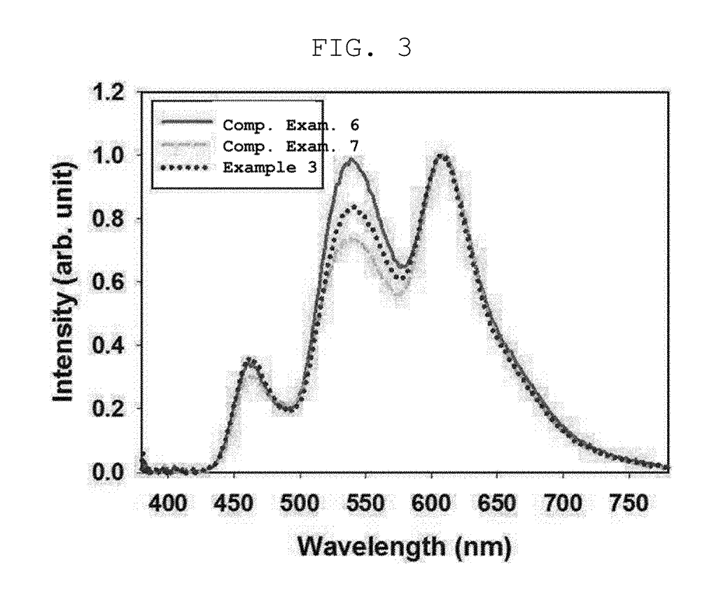

FIG. 2 is a graph illustrating electroluminescence (EL) spectra of tandem OLEDs according to Example 1, Comparative Example 1, Comparative Example 2, and Comparative Example 3. Referring to Table 1, representing the operating voltages, power efficiencies, CIEs, and CRIs of the tandem OLEDs according to Example 1, Comparative Example 1, Comparative Example 2, and Comparative Example 3, it can be appreciated that, in Example 1 having the blue emissive layer, the yellow emissive layer, and the red emissive layer sequentially arranged from the anode, the CRI is slightly lower than those of Comparative Example 1 and Comparative Example 3. In addition, the driving voltage of Example 1 is lower than those of Comparative Examples 1, 2, and 3, and the power efficiency of Example 1 is significantly higher.

### EXAMPLE 2

In a tandem OLED having the same structure as Example 1, the distance between the blue emissive layer and the cathode, the distance between the yellow emissive layer and the cathode, and the distance between the red emissive layer and the cathode were controlled to be 292 nm, 200 nm, and 60 nm, respectively.

### COMPARATIVE EXAMPLE 4

In a tandem OLED having the same structure as Example 1, the distance between the blue emissive layer and the cathode, the distance between the yellow emissive layer and the cathode, and the distance between the red emissive layer and the cathode were controlled to be 312 nm, 220 nm, and 60 nm, respectively.

### COMPARATIVE EXAMPLE 5

In a tandem OLED having the same structure as Example 1, the distance between the blue emissive layer and the cathode, the distance between the yellow emissive layer and the cathode, and the distance between the red emissive layer and the cathode were controlled to be 284 nm, 192 nm, and 60 nm, respectively.

TABLE 2

| @3,000 nits | Example 2 | Comp. Exam. 4 | Comp. Exam. 5 |
|---|---|---|---|
| Operating Voltage (V) | 9.62 | 10.6 | 9.84 |
| Power Efficiency | 44.9 | 22.7 | 34.4 |
| (lm/W) | | | |
| CIE (x, y) | (0.465, 0.448) | (0.508, 0.438) | (0.448, 0.455) |
| CRI | 80.5 | 75.5 | 75.0 |

Referring to Table 2, representing the operating voltages, power efficiencies, CIEs, and CRIs of the tandem OLEDs according to Example 2, Comparative Example 4, and Comparative Example 5, it can be appreciated that, in Example 2 in which the distance between the blue emissive layer and the cathode, the distance between the yellow emissive layer and the cathode, and the distance between the red emissive layer and the cathode were controlled to be 292 nm, 200 nm, and 60 nm, respectively, the driving voltage is lower than those of Comparative Example 4 and Comparative Example 5, the power efficiency is outstandingly higher, and the CRI is relatively excellent.

### EXAMPLE 3

In a tandem OLED having the same structure as Example 2, the distance between the blue emissive layer and the anode was controlled to be 95 nm.

### COMPARATIVE EXAMPLE 6

In a tandem OLED having the same structure as Example 2, the distance between the blue emissive layer and the anode was controlled to be 65 nm.

### COMPARATIVE EXAMPLE 7

In a tandem OLED having the same structure as Example 2, the distance between the blue emissive layer and the anode was controlled to be 125 nm.

TABLE 3

| @3,000 nits | Example 3 | Comp. Exam. 6 | Comp. Exam. 7 |
|---|---|---|---|
| Operating Voltage (V) | 8.34 | 8.51 | 8.51 |
| Power Efficiency | 43.5 | 44.5 | 43.8 |
| (lm/W) | | | |
| CIE (x, y) | (0.427, 0.450) | (0.420, 0.465) | (0.436, 0.448) |
| CRI | 81.9 | 79.3 | 85.8 |

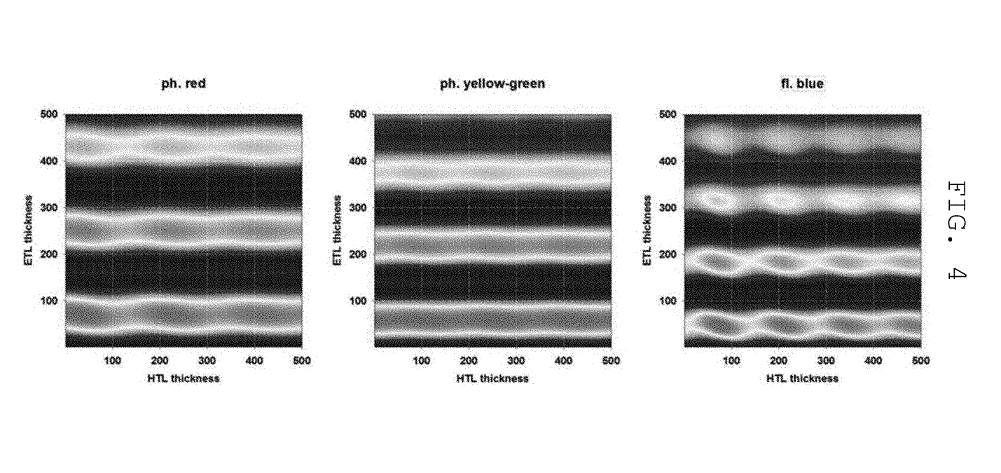

FIG. 3 is a graph illustrating EL spectra of tandem OLEDs according to Example 3, Comparative Example 6, and Comparative Example 7. Referring to Table 3, representing the operating voltages, power efficiencies, CIEs, and CRIs of the tandem OLEDs according to Example 3, Comparative Example 6, and Comparative Example 7, it can be appreciated that, in Example 3 in which the distance between the blue emissive layer and the anode was controlled to be 95 nm, the operating voltage is lower than those of Comparative Example 6 and Comparative Example 7, and the power efficiency and the CRI are not significantly different.

Summarizing Examples 1 to 3 and Comparative Examples 1 to 7, it can be appreciated that the optimal arrangement structure of the emissive layers in a tandem OLED includes the blue emissive layer, the yellow emissive layer, and the red emissive layer sequentially arranged from the anode, with the distance between the blue emissive layer and the cathode, the distance between the yellow emissive layer and the cathode, and the red emissive layer and the cathode being set to be 292 nm, 200 nm, and 60 nm, and the distance between the blue emissive layer and the anode being set to be 95 nm.

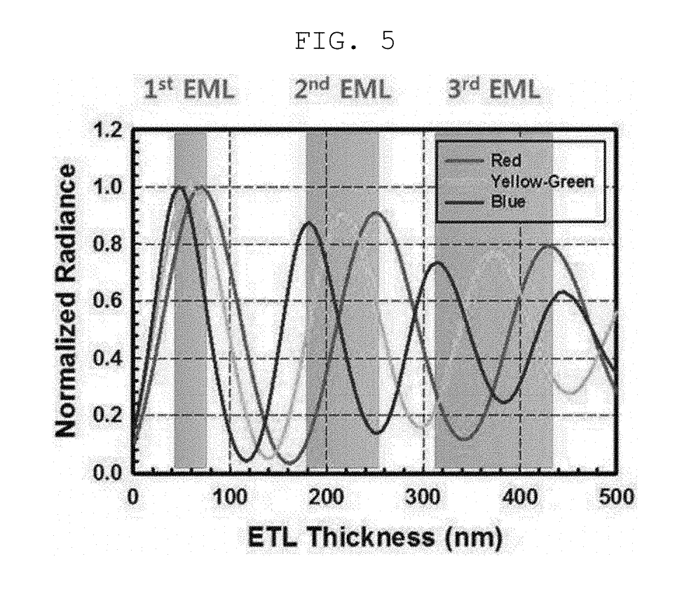

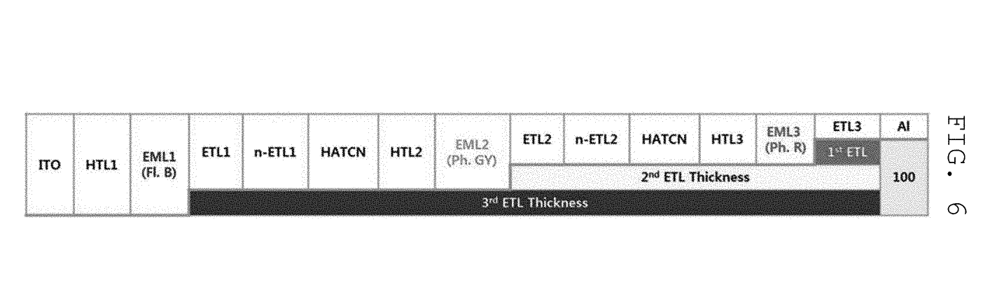

FIG. 4 illustrates simulated contour plots of normalized radiance intensity of normalized radiance intensity, while FIG. 5 illustrates normalized radiances depending on the thicknesses of electron layers.

Prior to fabrication of triple-stack tandem devices, phosphorescent red, yellow-green and fluorescent blue bottom emission unit devices were fabricated. The radiance distribution of emissive layers was simulated by changing the thicknesses of electron layers and hole layers. Consequently, as illustrated in the drawings, it can be appreciated that the radiance distribution is more sensitive to the thickness of the electron layers than the thickness of the hole layers.

FIG. 6 is conceptual view illustrating the thicknesses of electron layers in triple-stack tandem structures.

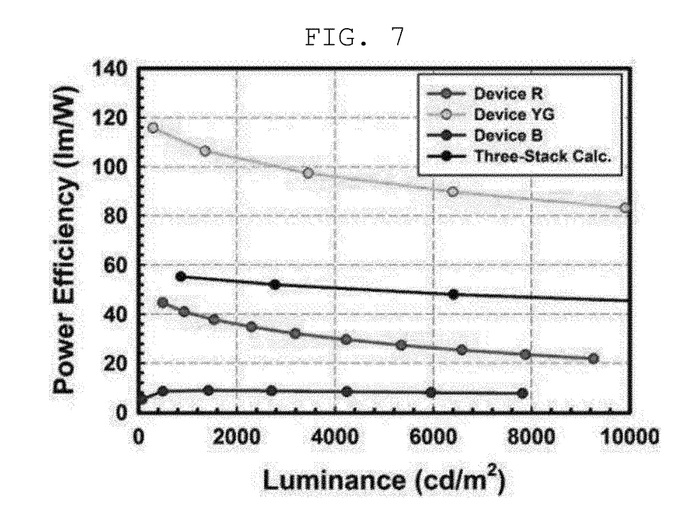

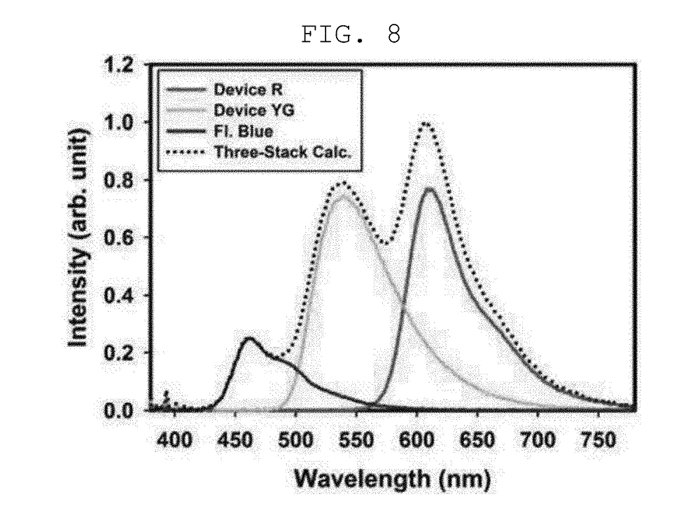

FIGS. 7 and 8 illustrate power efficiencies and EL spectra of fabricated unit devices.

Monochromatic OLEDs were fabricated. The dimensions of these OLEDs are as follows.

Device R (red): ITO (150 nm), p-hole layer (82 nm), hole layer (43 nm), R-emissive layer (15 nm), electron layer (10 nm), n-electron layer (50 nm), and Al (100 nm).

Device YG (Yellow-Green): ITO (150 nm), p-hole layer (82 nm), hole layer (43 nm), YG-emissive layer (15 nm, electron layer (10 nm), n-electron layer (40 nm), and Al (100 nm).

Device B (Blue): ITO (150 nm), p-hole layer (40 nm), hole layer (25 nm), B-emissive layer (15 nm), electron layer (10 nm), n-electron layer (20 nm), and Al (100 nm).

As illustrated in FIG. 7, power efficiencies of 40.6 lm/W (22.8%), 109.4 lm/W (24.0%), and 8.7 lm/W (5.1%) were obtained from device R (2.5V), device YG (2.5V), and device B (2.9V), respectively. The power efficiency of a triple-stack tandem white device can be estimated based on these results, on the assumption that there is no electric or optical loss originating from the interconnection of the units. The calculated power efficiency (PE) and external quantum efficiency (EQE) of the triple-stack white device are 55 lm/W and 52% at 1000 nit (7.5V)

As illustrated in FIG. 8, the EL spectrum of the tandem device can be calculated by overlapping the normalized unit spectra.

The foregoing descriptions of specific exemplary embodiments of the present disclosure have been presented with respect to the drawings and are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

### DESCRIPTION OF REFERENCE NUMERALS OF DRAWINGS

| | |
|---|---|
| 100: tandem OLED | 110: base substrate |
| 120: first electrode | 130: second electrode |
| 140: first organic light-emitting layer | |
| 141: first emissive layer | |
| 150: second organic light-emitting layer | |
| 151: second emissive layer | |
| 160: third organic light-emitting layer | |
| 161: third emissive layer | |
| 170: first CGL | 180: second CGL |
| 142, 152, 162: hole layer | 143, 153, 163: electron layer |

1. A tandem organic light-emitting device comprising:
a base substrate;
a first electrode disposed on the base substrate;
a second electrode facing the first electrode;
first to third organic light-emitting layers sequentially disposed from the first electrode, between the first electrode and the second electrode,
wherein the first organic light-emitting layer comprises a first emissive layer generating blue light, the second organic light-emitting layer comprises a second emissive layer generating yellow light, and the third organic light-emitting layer comprises a third emissive layer generating red light.

2. The tandem organic light-emitting device of claim 1, wherein a distance between the second emissive layer and the third emissive layer is greater than a distance between the first emissive layer and the second emissive layer and a distance between the third emissive layer and the second electrode.

3. The tandem organic light-emitting device of claim 2, wherein the distance between the second emissive layer and the third emissive layer ranges from 100 nm to 300 nm.

4. The tandem organic light-emitting device of claim 3, wherein the distance between the first emissive layer and the second emissive layer and the distance between the third emissive layer and the second electrode are less than 100 nm.

5. The tandem organic light-emitting device of claim 1, wherein, when a distance between the first electrode and the second electrode is 500 nm or less, a distance between the first emissive layer and the second electrode is 292 nm, a distance between the second emissive layer and the second electrode is 200 nm, a distance between the third emissive layer and the second electrode is 60 nm, and a distance between the first electrode and the first emissive layer is 95 nm.

6. The tandem organic light-emitting device of claim 1, further comprising:
a first charge generation layer situated between the first organic light-emitting layer and the second organic light-emitting layer; and
a second charge generation layer situated between the second organic light-emitting layer and the third organic light-emitting layer.

7. The tandem organic light-emitting device of claim 6, further comprising a third charge generation layer situated between the first organic light-emitting layer and the first electrode.

8. The tandem organic light-emitting device of claim 1, wherein a hole layer is disposed on one surface of each of the first to third emissive layers, and an electron layer is disposed on the other surface of each of the first to third emissive layers,
wherein the hole layer is disposed in a direction of the first electrode, and the electron layer is disposed in a direction of the second electrode.

9. The tandem organic light-emitting device of claim 1, wherein the base substrate is a flexible substrate.

10. The tandem organic light-emitting device of claim 9, wherein the base substrate is a thin glass sheet having a thickness of 1.5 mm or less.
